(19) United States
(12) Patent Application Publication
(10) Pub. No.: US 2020/0207142 A1
(43) Pub. Date: Jul. 2, 2020

(54) Liquid Photopolymer Resin Compositions for Flexographic Printing

(71) Applicant: MacDermid Graphics Solutions LLC, Waterbury, CT (US)

(72) Inventors: Ryan Vest, Mequon, WI (US); Deborah Johnson, Powder Springs, GA (US)

(21) Appl. No.: 16/238,007

(22) Filed: Jan. 2, 2019

(51) Int. Cl. B41N 1/12; B41C 1/00; C09D 11/101; C09D 11/107; G03F 7/031

(52) U.S. Cl. CPC B41N 1/12; B41C 1/003; G03F 7/031; C09D 11/107; C09D 11/101

(57) ABSTRACT

A liquid photopolymer resin composition comprising: a) at least one ethylenically unsaturated prepolymer; b) at least one ethylenically unsaturated monomer; c) at least one photoinitiator; and d) at least one polythiol and a method of using the same to make soft relief image printing plates that have good tensile strength and elongation.

### FIELD OF THE INVENTION

The present invention relates generally to a liquid photopolymer composition that is usable in the manufacture of relief image printing elements and coatings through photopolymerization.

### BACKGROUND OF THE INVENTION

Flexography is a method of printing that is commonly used for high-volume runs. Flexography is employed for printing on a variety of substrates such as paper, paperboard stock, corrugated board, films, foils and laminates. Newspapers and grocery bags are prominent examples. Coarse surfaces and stretch films can be economically printed only by means of flexography.

Photosensitive printing elements generally comprise a support layer, one or more photosensitive layers, an optional slip film release layer, and an optional protective cover sheet. The protective cover sheet is formed from plastic or any other removable material that can protect the plate or photocurable element from damage until it is ready for use. If used, the slip film release layer is typically disposed between the protective cover sheet and the photocurable layer(s) to protect the plate from contamination, increase ease of handling, and act as an ink-accepting layer. After exposure and development, the photopolymer flexographic printing plate consists of various image elements supported by a floor layer and anchored to a backing substrate.

It is highly desirable that flexographic printing plates work well under a wide range of conditions. For example, the printing plates should be able to impart their relief image to a wide range of substrates, including cardboard, coated paper, newspaper, calendared paper, and polymeric films such as polypropylene. Importantly, the image should be transferred quickly and with fidelity, for as many prints as the printer desires to make.

The demands placed on flexographic printing plates are considerable. For example, a flexographic printing pate must have sufficient flexibility to wrap around a printing cylinder, yet be strong enough to withstand the rigors experienced during a typical printing process. The printing plate should exhibit a low hardness to facilitate ink transfer during printing. It is also important that the surface of the printing plate be dimensionally stable during storage. In addition, the printing plate must also have a relief image that has a chemical resistance against the aqueous-based or alcohol-based inks that are typically used in flexographic printing. Finally, it is also highly desirable that the physical and printing properties of the printing plate are stable and remain unchanged during printing.

Flexographic printing elements can be manufactured in various ways including with sheet polymers and by the processing of liquid photopolymer resins. Flexographic printing elements made from liquid photopolymer resins have the advantage that uncured resin can be reclaimed from the non-image areas of the printing elements and used to make additional printing plates. Liquid photopolymer resins have a further advantage as compared to sheet polymers in terms of flexibility, which enables the production of any required plate gauge simply by changing the machine settings.

Various processes have been developed for producing printing plates from liquid photopolymer resins as described, for example, in U.S. Pat. Pub. No. 2012/0082932 to Battisti et al., U.S. Pat. Pub. No. 2014/0080042 to Maneira, U.S. Pat. No. 5,213,949 to Kojima et al., U.S. Pat. No. 5,813,342 to Strong et al., U.S. Pat. Pub. No. 2008/0107908 to Long et al., and in U.S. Pat. No. 3,597,080 to Gush, the subject matter of each of which is herein incorporated by reference in its entirety.

Typical steps in the liquid platemaking process include:
(1) casting and exposure;
(2) reclamation;
(3) washout;
(4) post exposure;
(5) drying; and
(6) detackification.

In the casting and exposure step, a photographic negative is placed on a bottom glass platen and a coverfilm is placed over the negative in an exposure unit. The exposure unit generally comprises the bottom glass paten with a source of UV light below it (lower lights) and lid having flat top glass platen with a source of UV light above it (upper lights).

All of the air is removed by vacuum so that any wrinkling of the negative or coverfilm can be eliminated. In addition, the bottom glass platen may be grooved to further remove any air between the coverfilm and the negative. Thereafter, a layer of liquid photopolymer and a backing sheet (i.e., a thin layer of polyester or polyethylene terephthalate) are cast on top of the coverfilm and negative to a predetermined thickness. A backing sheet, which may be coated on one side to bond with the liquid photopolymer, is laminated over the cast liquid photopolymer layer to serve as the back of the plate after exposure.

Upper and/or lower sources of actinic radiation (i.e., the upper and lower lights) are used to expose the photopolymer to actinic radiation to selectively crosslink and cure the liquid photopolymer layer in the areas not covered by the negative. The upper lights are used to create the floor layer of the printing plate (i.e., back exposure) while the lower lights are used to face expose the photopolymer to actinic radiation through the negative to create the relief image. Plate gauge may be set by positioning a top exposure glass at a desired distance from a bottom exposure glass after dispensing liquid photopolymer on the protected bottom exposure glass.

The upper lights are turned on for a prescribed amount of time to cause the photopolymer adjacent to the substrate to crosslink uniformly over the entire surface of the plate, forming the floor. Thereafter, areas to be imaged are exposed to actinic radiation from the lower lights (i.e., through the bottom glass platen). The actinic radiation shines through the clear areas of the negative, which causes the photopolymer to crosslink in those areas, forming the relief image that bonds to the floor layer. The liquid photopolymer that is not exposed to the lower lights (i.e., the uncured photopolymer) remains in a liquid state and can be reclaimed and reused.

After the exposure is complete, the printing plate is removed from the exposure unit. In all areas not exposed to UV radiation, the resin remains liquid after exposure and can be reclaimed. In a typical process, the uncured resin is physically removed from the plate in a process step so that the uncured resin can be reused in making additional plates. This “reclamation” step typically involves squeegeeing, vacuuming or otherwise removing liquid photopolymer remaining on the surface of the printing plate, and, not only saves material costs of the photopolymer resin, but also reduces the use and cost of developing chemistry and makes a lighter plate that is safer and easier to handle.

Any residual traces of liquid resin remaining after the reclamation step may be removed by nozzle washing or brush washing using a wash-out solution to obtain a washed-out plate, leaving behind the cured relief image. Typically, the plate is placed into a washout unit wherein an aqueous solution comprising soap and/or detergent is used to wash away any residual unexposed photopolymer. After development, a relief image formed of cured photopolymerizable resin is obtained. The cured resin is likewise insoluble in certain inks, and is usable in flexographic printing.

After the washout step has been completed, the printing plate may be subjected to various post exposure and detackification steps. Post exposure may involve submerging the plate in a water and salt solution and performing an additional exposure of the printing plate to actinic radiation (UV light) to fully cure the printing plate and to increase plate strength. The printing plate may then be rinsed and dried by blowing hot air onto the plate, by using an infrared heater or by placing the printing plate into a post exposure oven.

If used, the detackification step may involve the use of a germicidal unit (light finisher) to ensure a totally tack-free plate surface. This step is not require for all plates, as certain resins may be tack-free and thus printing press ready without the need for the detackification step.

Liquid photopolymer compositions are described, for example, in U.S. Pat. No. 2,760,863 to Plambeck, U.S. Pat. Nos. 3,960,572 and 4,006,024 to Ibata et al., U.S. Pat. Nos. 4,137,081, 4,174,218 and 4,442,302 to Pohl, U.S. Pat. No. 4,857,434 to Klinger, and U.S. Pat. Pub. No. 2003/0152870 to Huang, the subject matter of each of which is herein incorporated by reference in its entirety.

Conventional formulation strategies for preparing soft printing plates from liquid photopolymer materials generally involve the usage of a soft prepolymer in the photopolymer composition, which in turn requires modifications to the stoichiometric amounts of polyol and isocyanate in the prepolymer, as described, for example, in U.S. Pat. Pub. No. 2003/0152870 to Huang, the subject matter of which is herein incorporated by reference in its entirety. However, this approach can require either the development of a new prepolymer altogether, or can lead to the reduction in physical properties due to the softness of the resulting plate as well as the lower tensile strength. Other formulation strategies involve the reduction of multifunctional monomers, such as di- or tri-functional monomers. However, this can also impact the physical strength of the resulting resin.

One important substrate for flexographic printing is liner board having a fluted backing, e.g., corrugated cardboard which has a layer of fluting between two flat sheets. The flats sheets, onto which printing is desirably placed, often have slight indentations due to the uneven support of the underlying fluting. In order to obtain a good result when printing on corrugated substrates, it is desirable to have as soft a printing plate as possible so that the printing plate may more readily conform to the surface of the corrugated board. However at the same time, the plate must also still exhibit other important properties, including durability and resilience.

There remains a need in the art for an improved soft relief photopolymer printing element prepared from liquid photopolymer resins, where such printing plates are especially suited for printing on corrugated substrates and meet or exceed the printing quality and durability demanded by the printing industry.

### SUMMARY OF THE INVENTION

It is an object of the present invention to provide an improved liquid photopolymer resin composition.

It is another object of the present invention to provide an improved liquid photopolymer resin composition capable of producing soft relief image printing plates that exhibit good durability.

It is still another object of the present invention to provide an improved liquid photopolymer resin composition capable of producing soft relief image printing plates that exhibit sufficient resilience.

It is still another object of the present invention to provide an improved liquid photopolymer resin composition capable of producing soft relief image printing plates that is suitable for producing a good result when printing on corrugated substrates.

It is still another object of the present invention to provide an improved liquid photopolymer resin composition capable of producing soft relief image printing plates that meets or exceeds print quality and durability standards.

To that end, in one embodiment, the present invention relates generally to a liquid photopolymer resin composition comprising:
a) at least one ethylenically unsaturated polyurethane prepolymer;
b) at least one ethylenically unsaturated monomer;
c) at least one photoinitiator; and
d) at least one polythiol.

In another embodiment, the present invention relates generally to a method of making a relief image printing plate from a liquid photoresin, the method comprising the steps of:
a) casting a liquid photoresin composition on top of a coverfilm to a predetermined thickness, wherein the liquid photoresin composition comprises:
   i) at least one ethylenically unsaturated prepolymer;
   ii) at least one ethylenically unsaturated monomer;
   iii) at least one photoinitiator; and
   iv) at least one polythiol;
b) laminating a backing sheet over the cast liquid photopolymer;
c) exposing the photopolymer to actinic radiation to selectively crosslink and cure the liquid photopolymer, wherein the liquid photopolymer that is not exposed to actinic radiation remains in a liquid state; and
d) removing the liquid photopolymer;
wherein a relief image of cured photopolymer is obtained.

### DETAILED DESCRIPTION OF THE PREFERRED EMBODIMENTS

As described herein, in one embodiment, the present invention relates generally to a liquid photopolymer resin composition comprising:
a) at least one ethylenically unsaturated prepolymer;
b) at least one ethylenically unsaturated monomer;
c) at least one photoinitiator; and
d) at least one polythiol.

The present invention utilizes a typical formulating approach, which requires no special prepolymer structure and no intentional removal or dramatic reduction in crosslink density. As a result, there is also no dramatic reduction in the strength of the resulting photopolymer.

The use of thiols in the compositions results in an adjustment in the crosslink mechanism in the presence of acrylate/methacrylate monomers, which results in a lower Shore A material with little or no change in the physical toughness of the resulting photopolymer. The photoresins described herein are liquid photopolymer resins, meaning that the uncured photoresin is a liquid at room temperature. Thus, once portions of the liquid photoresin are crosslinked and cured, the remaining photoresin can be reclaimed and reused.

The ethylenically unsaturated prepolymer may include, for example, unsaturated polyester resins, unsaturated polyurethane resins, unsaturated polyamide resins and unsaturated poly(meth)acrylate resins, such as, for example polyether urethane polymers, or polyether polyester urethane copolymers such as polyether polyester urethane methacrylate photopolymers.

Typically, the ethylenically unsaturated prepolymer is present in the liquid photosensitive composition at a concentration of between about 60 to about 80 percent by weight of the photosensitive resin composition, more preferably from about 65 to about 75 percent by weight of the photosensitive resin composition.

The ethylenically unsaturated monomer may be any commonly available acrylate or methacrylate such as isobornylester, t-butylester, laurylester, monoesters or diesters of acrylic acid or methacrylic acid, and/or triesters of trimethylopropanol or propoxylated trimethylolpropanol. However, the use of a monomer having two or more ethylenically unsaturated groups in the monomer increases the hardness of the resultant printing plate. Thus, the amount of monomers with two or more ethylenically unsaturated groups must be controlled.

Suitable monomers include, for example, the esters of acrylic acid and/or methacrylic acid with monohydric or polyhydric alcohols, such as, for example and without limitation, butyl acrylate, 2-ethylhexyl acrylate, isodecyl acrylate, lauryl acrylate, phenoethoxy acrylate, ethylene glycol diacrylate, 2-hydroxyethyl acrylate, hexane-1,6-diol diacrylate, 1,1,1-trimethylolpropane triacrylate, di, tri, and tetraethylene glycol diacrylate, tripropylene glycol diacrylate, pentaerythritol tetraacrylate, propoxylated trimethylolpropane mono- di- and tri-acrylate, ethoxylated trimethylolpropane triacrylate, and oligomeric polybutadienes with acrylic acid, i.e., oligomeric polybutadienes possessing activated, photopolymerizable olefinic double bonds, butyl methacrylate, 2-ethylhexyl methacrylate, isodecyl methacrylate, lauryl methacrylate, phenoethoxy methacrylate, ethylene glycol dimethacrylate, 2-hydroxyethyl methacrylate, hexane-1,6-diol dimethacrylate, 1,1,1-trimethylolpropane trimethacrylate, di, tri, and tetraethylene glycol dimethacrylate, tripropylene glycol dimethacrylate, pentaerythritol tetramethacrylate, propoxylated trimethylolpropane mono- di- and tri-methacrylate, ethoxylated trimethylolpropane trimethacrylate, and oligomeric polybutadienes with methacrylic acid, i.e., oligomeric polybutadienes possessing activated, photopolymerizable olefinic double bonds.

It is preferred that the ethylenically unsaturated monomer comprise a mixture of monomers with some having one ethylenically unsaturated group and some having two or more ethylenically unsaturated groups. The optimum ratio of the mixture will be determined in part by the desired hardness of the resulting printing plate. The amount of the monomer or monomer mixture will also have an effect on the viscosity of the photosensitive resin. The greater the amount of the monomer or monomer mixture, the lower the resultant viscosity of the photosensitive resin. The viscosity of the photosensitive resin is preferably between 10,000 cps and 100,000 cps at room temperature and more preferably between 20,000 cps and 50,000 cps.

Typically, the one or more ethylenically unsaturated monomers are present in the liquid photosensitive composition in a total amount from about 10 to about 40 percent by weight of the photosensitive resin composition, more preferably from about 15 to about 30 percent by weight of the photosensitive resin composition.

The photoinitiator may be any of a number of photoinitiators commonly used in photoresin compositions and combinations thereof. Examples of suitable photoinitiators include, for example, one or more of acenaphthenequinone, acylphosphine oxide, α-aminoacetophenone, benzanthraquinone, benzoin methyl ether, benzoin isopropyl ether, benzoin n-butyl ether, benzoin isobutyl ether, benzophenone, benzoyl dimethyl ketal, benzophenone, benzil dimethyl acetal, benzil 1-methyl 1-ethyl acetal, camphorquinone, chloroacetophenone, 2-chlorothioxanethone, dibenzosuberone, 2,2-diethoxy-2-phenylacetophenone, 2,2-diethoxyacetophenone, 2-dimethoxybenzoyldiphenylphosphine oxide, 2,2-dimethoxy-2-phenylacetophenone (i.e., Irgacure® 651), 4,4′-bis(dimethylamino)benzophenone, 2-ethylanthraquinone, ethyl 2,4,6-trimethylbenzoylphenyl phosphinate, exanophenone, hydroxyacetophenone, 2-hydroxy-2-methylpropiophenone, 2-hydroxy-2-methyl-4′-isopropylisopropiophenone, 1-hydroxycyclohexyl phenyl ketone, 3-ketocoumarin, o-methoxybenzophenone, (methyl)-benzoylbenzoate, methylbenzoyl formate, Michler's ketone, 4′-morpholinodeoxybenzoin, 4-morpholinobenzophenone, α-phenylbutyrophenone, sodium 2,4,6-trimethylbenzoylphenylphosphinate, thioxanone, thioxanethone, 10-thioxanthenone, thioxanthen-9-one, tetramethylthiuram monosulfide, 3,3′,4,4′-tetra(t-butylperoxicarbonyl)-benzophenone, trichloroacetophenone, 2,4,6-trimethylbenzoyldiphenylphosphine oxide, valerophenone, axanethone, p-diacetylbenzene, 4-aminobenzophenone, 4′-methoxyacetophenone, benzaldehyde, alpha-tetralone, 9-acetylphenanthrene, 2-acetylphenanthrene, 3-acetylphenanthrene, 3-acetylindone, 9-fluorenone, 1-indanone, 1,3,5-triacetylbenzene, xanthene-9-one, 7-H-benz[de]anthracen-7-one, 1-naphthaldehyde, 4,4′-bis(dimethylamino)-benzophenone, fluorene-9-one, 1′-acetonaphthone, 2′-acetonaphthone, 2,3-butanedione, acetonaphthene benz[a]anthracene 7.12 diene, among others. Phosphines such as triphenylphosphine and tri-o-tolylphosphine are also operable herein as photoinitiators.

The photoinitiators described herein can be used alone or in combination with coinitiators, e.g., ethylanthraquinone with 4,4′,-bis(dimethylamino)benzophenone, benzoin methyl ether with triphenylphosphine, diacylphosphine oxides with tertiary amines or acyldiarylphosphine oxides with benzil dimethyl acetal.

The amount of the photoinitiator can be any effective concentration that will allow the formation of a floor layer to the flexographic printing plate via a back exposure of a reasonable length of time and the formation of the relief image with the required image resolution. This time is related to the type of image being formed, as well as the thickness of the desired flexographic printing plate. The effective amount of photoinitiator is dependent on the type of initiator chosen. However, a concentration range of about 0.1 to about 10 percent by weight, more preferably about 0.5 to about 5 percent by weight, of the photoinitiator is generally preferred.

Particularly preferred photoinitiators include one or more of 2,2-dimethoxy-2-phenylacetophenone and benzophenone.

To protect the photopolymer mixtures from decomposition by thermal oxidation and oxidation by atmospheric oxygen, effective amounts of antioxidants may also be added to the photopolymer mixture, including, for example, sterically hindered monophenols, such as butylated hydroxytoluene (BHT), alkylated thiobisphenols and alkylidene bisphenols, such as 2,2-methylenebis-(4-methyl-6-tert-butylphenol) and 2,2-bis (1-hydroxy-4-methyl-6-tert-butylphenyl) sulfide, hydroxybenzyls, such as 1,3,5-trimethyl-2,4,6-tris-(3,5-di-tert-butyl-4-hydroxybenzyl)benzene, triazines, such as 2-(4-hydroxy-3,5-tert-butylanilino)-4,6-bis-(n-octylthio)-1,3,5-triazine, polymerized trimethyldihydroquinone, dibutylzinc dithiocarbamate, dilauryl thiodipropionate and phosphites, such as tris (nonylphenyl) phosphite. In one embodiment, the antioxidant is BHT.

As described herein, the composition of the present invention also includes a polythiol, which enables the development of soft liquid photopolymer resins that are capable of producing relief image printing plates having a Shore A durometer of less than about 30, more preferably less than about 25 and most preferably less than about 20, at ambient conditions, while maintaining the strength of the resin.

In a preferred embodiment, the polythiols is a simple or complex organic compound having multiple pendant or terminally positioned —SH functional groups per average molecule. Suitable polythiols have molecular weights of from about 100 to about 20,000 or more, more preferably from about 100 to about 10,000.

The polythiol can generally be any compound that comprises molecules having two or more thiol groups per molecule. Examples of preferred polythiol compounds because of their relatively low odor level include but are not limited to esters of thioglycolic acid (HS—CH₂COOH), α-mercaptopropionic acid (HS—CH(CH₃)—COOH and β-mercaptopropionic acid (HS—CH₂CH₂COOH) with polyhydroxy compounds such as glycols, triols, tetraols, pentaols, hexaols, and the like. Specific examples of the preferred polythiols include but are not limited to ethylene glycol bis(thioglycolate), ethylene glycol bis(β-mercaptopropionate), trimethylolpropane tris(thioglycolate), trimethylolpropane tris(β-mercaptopropionate), pentaerythritol tetrakis(β-mercaptopropionate), all of which are commercially available. Poly-α-mercaptoacetate or poly-β-mercaptopropionate esters, particularly the trimethylopropane triesters or pentaerythritol tetra esters are preferred. Other polythiols which can be suitably employed include alkyl thiol functional compounds such as 1,2-dimercapthoethane, 1,6-dimercaptohexane and the like. Thiol terminated polysulfide resins may also be employed.

Suitable examples of aliphatic and cycloaliphatic dithiols include 1,2-ethanedithiol, butanedithiol, 1,3-propanedithiol, 1,5-pentanedithiol, 2,3-dimercapto-1-propanol, dithioerythritol, 3,6-dioxa-1,8-octanedithiol, 1,8-octanedithiol hexanedithiol, dithiodiglycol, pentanedithiol, decanedithiol, 2-methyl 1,4 butanedithiol, bis-mercaptoethylphenyl methane, 1,9-nonanedithiol(1,9-dimercaptononane), glycol dimercaptoacetate, 3-mercapto-β,4-dimethyl-cyclohexaneethanethiol, cyclohexane dimethane dithiol, and 3,7-dithia-1,9-nonanedithiol.

Suitable examples of aromatic dithiols include 1,2-benzenedithiol, 1,3-benzenedithiol, 1,4-benzenedithiol, 2,4,6-trimethyl-1,3-benzenedimethanethiol, durene-.alpha.1,.alpha.2-dithiol, 3,4-dimercaptotoluene, 4-methyl-1,2-benzenedithiol, 2,5-dimercapto-1,3,4-thiadiazole, 4,4′-thiobisbezenedithiol, bis(4-mercaptophenyl)-2,2′-propane(bisphenol dithiol), and [1,1′-biphenyl]-4,4′-dithiol, and p-xylene-α,α-dithiol.

Suitable examples of oligomeric dithiols include difunctional mercapto functional urethane oligomers derived from end capping moieties of hydroxyethyl mercaptan, hydroxypropyl mercaptan, dimercaptopropane, dimercapto ethane. Examples of suitable trithiol functional compounds include, trimethylolethane tris-mercaptopropionate, trimethylolpropane tris-mercaptopropionate, trimethylolethane tris-mercaptoacetate, and trimethylolpropane tris-mercaptoaacetate glycerol tri(1,1-mercaptoundecate), trimethylol propane tri(1,1-mercaptoundecate). One preferred trithiol is trimethylolpropane tris(2-mercaptopropionate).

Examples of suitable tetrafunctional thiols include pentaerythritol tetramercapto propionate, pentaerythritol tetramercapto acetate, and pentaethritol tetra(1,1-mercaptoundecate)

Multi-functional thiols can be obtained by reacting thioalkyl carboxylic acids, e.g., thioglycolic acid, mercapto propionic acid with high functional alcohols, amines and thiols. Furthermore, multifunctional thiols can be obtained by reacting mercapto alkyl trialkoxy silanes with silanols that may be polymeric or silica based silanols.

Other preferred multifunctional thiols are obtained using thiol carboxylic acids (HS—R—COOH) where R is an alkyl or aryl group, e.g., thioundecanoic acid of which the COOH groups are reacted with reactive enes, alcohols, thiols or amines that are multifunctional.

Particularly preferred polythiols for use in the compositions described herein include trimethylolpropane tris(3-mercaptopropionate) and pentaerythritol tetrakis(β-mercaptopropionate).

The polythiol is preferably used in the liquid photosensitive composition in an amount of about 0.10 to about 3.0 percent by weight of the photosensitive resin composition, more preferably from about 0.25 to about 2.0 percent by weight of the photosensitive resin composition.

The liquid photoresin compositions may also, optionally, but preferably, comprise a variety of slip additives, dyes, stabilizers and other additives of a similar nature which are typically added to photosensitive resin compositions.

Thus, the liquid photopolymer resin may include, for example, one or more of antioxidants, accelerators, dyes, inhibitors, activators, fillers, pigments, antistatic agents, flame-retardant agents, thickeners, thixotropic agents, surface active agents, light scattering agents, viscosity modifiers, extending oils, plasticizers, and detackifiers, by way of example and not limitation. These additives may be pre-blended with one or monomers or other compounds to be polymerized. Various fillers, including for example, natural and synthetic resins, carbon black, glass fibers, wood flour, clay, silica, alumina, carbonates, oxides, hydroxides, silicates, glass flakes, glass beads, borates, phosphates, diatomaceous earth, talc, kaolin, barium sulfate, calcium sulfate, calcium carbonate, antimony oxide, etc. may also be included in the photopolymer composition in amounts that will not interfere with or otherwise inhibit the photocuring reaction or other steps in the platemaking process.

Additionally, the liquid photopolymer resin composition may contain any one or more of a range of further performance-enhancing additives including, for example, esters of acrylic or methacrylic acid, stabilizers, defoamers, dyes and high molecular weight fatty acids, such as myristic acid, to ensure a dry, tack-free surface after post-curing of the washed plate.

The liquid photopolymer resin may be processed in a liquid platemaking process to produce a relief image printing element having the desired properties of Shore A hardness, elongation and tensile strength to produce a good printing result, especially when printing on corrugated substrates.

After processing the liquid photopolymer resin composition through the platemaking process, the resulting relief image printing plate preferably has a Shore A hardness of less than about 30, more preferably less than about 25 and most preferably less than about 20 under ambient conditions. The relief image printing plate also has an elongation in the 150 to 300% range, more preferably about 200 to about 250% and a tensile strength in the range of about 375 to about 700, more preferably about 450 to about 600 psi (as measured on an Instron system at 2 inches/minute sample speed).

### Example 1

The following formulation provided below in Table 1 demonstrates one exemplary liquid photopolymer formulation for producing relief image printing elements in accordance with the present invention.

TABLE 1
Liquid photopolymer formulation

| Element | % by Wt. |
|---|---|
| EU1 Prepolymer | 70.2 |
| BHT | 0.18 |
| 2,2-dimethyloxy-2pheyl-acetophenone | 0.25 |
| Benzophenone | 0.72 |
| Myristic Acid | 1.51 |
| Polypropylene glycol monomethacrylate | 10.97 |
| Lauryl methacrylate | 8.40 |
| Diethylene glycol dimethacrylate | 3.38 |
| N,N-dimethylaminoethyl methacrylate | 1.90 |
| Trimethylolpropane trimethacrylate | 1.47 |

In addition to the above ingredients, trimethylolpropane tris(3-mercaptopropionate) was added to the photoresin composition at a level of 0.50 percent by weight, 1.0 percent by weight and 1.5 percent by weight. Blocks having a thickness of 0.25 inches were crosslinked and cured and the Shore A Value of each of the formulations was measured using a Shore Si digital durometer. The results are provided below in Table 2.

TABLE 2
Summary of Shore A Values

| Wt. % polythiol | Shore A |
|---|---|
| 0 | 35 |
| 0.5 | 28.1 |
| 1.0 | 23.5 |
| 1.5 | 20.3 |

As seen in Table 2, the printing plates produced from the liquid photoresin composition containing a polythiol exhibited the desired properties of Shore.

The present invention also relates generally to a printing plate having a Shore A hardness of less than about 30, the printing plate comprising the photochemical reaction product of:
a) at least one ethylenically unsaturated prepolymer;
b) at least one ethylenically unsaturated monomer;
c) at least one photoinitiator; and
d) at least one polythiol.

In another embodiment, the present invention relates generally to a method of making a relief image printing plate from a liquid photoresin, the method comprising the steps of:
a) casting a liquid photoresin composition on top of a coverfilm to a predetermined thickness, wherein the liquid photoresin composition comprises:
   i) at least one ethylenically unsaturated prepolymer;
   ii) at least one ethylenically unsaturated monomer;
   iii) at least one photoinitiator; and
   iv) at least one polythiol;
b) laminating a backing sheet over the cast liquid photopolymer;
c) exposing the photopolymer to actinic radiation to selectively crosslink and cure the liquid photopolymer, wherein the liquid photopolymer that is not exposed to actinic radiation remains in a liquid state; and
d) removing the liquid photopolymer;
wherein a relief image of cured photopolymer is obtained.

The relief image printing plates produced in accordance with the present invention provide a good result when printing on corrugated substrates. The resulting printing plates have the desired softness to produce a good printing result but also have the necessary physical toughness and polymer strength necessary to reduce on press wear and damage.

What is claimed is:

1. A liquid photopolymer resin composition comprising:
a) at least one ethylenically unsaturated prepolymer;
b) at least one ethylenically unsaturated monomer;
c) at least one photoinitiator; and
d) at least one polythiol.

2. The liquid photopolymer resin according to claim 1, wherein the ethylenically unsaturated prepolymer comprises one or more of an unsaturated polyester resin, an unsaturated polyurethane resin, an unsaturated polyamide resins and an unsaturated poly(meth)acrylate resin.

3. The liquid photopolymer resin composition according to claim 1, wherein the ethylenically unsaturated monomer comprises a mixture of monomers having one ethylenically unsaturated group and monomers having two or more ethylenically unsaturated groups.

4. The liquid photopolymer resin composition according to claim 1, wherein the at least one polythiol is a compound comprising molecules having two or more thiol groups per molecule.

5. The liquid photopolymer resin composition according to claim 4, wherein the at least one polythiol is selected from the group consisting of esters of thioglycolic acid, α-mercaptopropionic acid and β-mercaptopropionic acid with polyhydroxy compounds.

6. The liquid photopolymer resin composition according to claim 5, wherein the at least one polythiol is selected from the group consisting of ethylene glycol bis(thioglycolate), ethylene glycol bis(β-mercaptopropionate), trimethylolpropane tris(thioglycolate), trimethylolpropane tris(β-mercaptopropionate), pentaerythritol tetrakis(β-mercaptopropionate), and combinations of one or more of the foregoing.

7. The liquid photopolymer resin composition according to claim 1, wherein the at least one polythiol is present in the liquid photopolymer resin composition in an amount of between about 0.10 and about 3.0 percent by weight.

8. The liquid photopolymer resin composition according to claim 7, wherein the at least one polythiol is present in the liquid photopolymer resin composition in an amount of between about 0.25 and about 2.0 percent by weight.

9. The liquid photopolymer resin composition according to claim 1, further comprising an additive selected from the group consisting of antioxidants, accelerators, dyes, inhibitors, activators, fillers, pigments, antistatic agents, flame-retardant agents, thickeners, thixotropic agents, surface active agents, light scattering agents, viscosity modifiers, extending oils, plasticizers, detackifiers and combinations of one or more of the foregoing.

10. The liquid photopolymer resin composition according to claim 9, wherein the additive comprises an antioxidant.

11. The liquid photopolymer resin composition according to claim 10, wherein the antioxidant is selected from the group consisting of sterically hindered monophenols, alkylated thiobisphenols and alkylidene bisphenols, hydroxybenzyls, triazines, polymerized trimethyldihydroquinone, dibutylzinc dithiocarbamate, dilauryl thiodipropionate, phosphites, and combinations of one or more of the foregoing.

12. The liquid photopolymer resin composition according to claim 1, further comprising a performance enhancing additive.

13. The liquid photopolymer resin composition according to claim 12, wherein the performance enhancing additive comprises a high molecular weight fatty acid.

14. A flexographic relief image printing plate comprising the photochemical reaction product of claim 1.

15. The flexographic relief image printing plate according to claim 14, wherein the printing plate has a Shore A hardness of less than about 30.

16. The flexographic relief image printing plate according to claim 15, wherein the printing plate has a Shore A hardness of less than about 25.

17. The flexographic relief image printing plate according to claim 16, wherein the printing plate has a Shore A hardness of less than about 20.

18. A method of making a relief image printing plate from a liquid photoresin, the method comprising the steps of:
a) casting a liquid photoresin composition on top of a coverfilm to a predetermined thickness, wherein the liquid photoresin composition comprises:
i) at least one ethylenically unsaturated prepolymer;
ii) at least one ethylenically unsaturated monomer;
iii) at least one photoinitiator; and
iv) at least one polythiol;
b) laminating a backing sheet over the cast liquid photopolymer;
c) exposing the photopolymer to actinic radiation to selectively crosslink and cure the liquid photopolymer, wherein the liquid photopolymer that is not exposed to actinic radiation remains in a liquid state; and
d) removing the liquid photopolymer;
wherein a relief image of cured photopolymer is obtained.

19. The method according to claim 18, wherein the at least one polythiol is a compound comprising molecules having two or more thiol groups per molecule.

20. The method according to claim 19, wherein the at least one polythiol is selected from the group consisting of esters of thioglycolic acid, α-mercaptopropionic acid and β-mercaptopropionic acid with polyhydroxy compounds.

21. The method according to claim 20, wherein the at least one polythiol is selected from the group consisting of ethylene glycol bis(thioglycolate), ethylene glycol bis(β-mercaptopropionate), trimethylolpropane tris(thioglycolate), trimethylolpropane tris(β-mercaptopropionate), pentaerythritol tetrakis(β-mercaptopropionate), and combinations of one or more of the foregoing.

22. The method according to claim 19, wherein the at least one polythiol is present in the liquid photopolymer resin composition in an amount of between about 0.10 and about 3.0 percent by weight.

23. The method according to claim 22, wherein the at least one polythiol is present in the liquid photopolymer resin composition in an amount of between about 0.25 and about 2.0 percent by weight.

24. The method according to claim 19, further comprising an additive selected from the group consisting of antioxidants, accelerators, dyes, inhibitors, activators, fillers, pigments, antistatic agents, flame-retardant agents, thickeners, thixotropic agents, surface active agents, light scattering agents, viscosity modifiers, extending oils, plasticizers, detackifiers and combinations of one or more of the foregoing.

25. The method according to claim 24, wherein the additive comprises an antioxidant.

26. The method according to claim 19, further comprising a performance enhancing additive.

27. The method according to claim 19, wherein the printing plate has a Shore A hardness of less than about 30.

28. The method according to claim 27, wherein the printing plate has a Shore A hardness of less than 25.

29. The method according to claim 28, wherein the printing plate has a Shore A hardness of less than 20.
